(19) United States
(12) Patent Application Publication
(10) Pub. No.: US 2024/0234345 A1
(43) Pub. Date: Jul. 11, 2024

(54) SYSTEMS AND METHODS FOR PROVIDING DISTRIBUTED BATTERIES IN INTEGRATED CIRCUITS

(71) Applicant: UNIVERSITY OF FLORIDA RESEARCH FOUNDATION, INCORPORATED, Gainesville, FL (US)

(72) Inventors: Swarup BHUNIA, Gainesville, FL (US); Peyman Dehghanzadeh, Gainesville, FL (US)

(21) Appl. No.: 18/537,160

(22) Filed: Dec. 12, 2023

Related U.S. Application Data
(60) Provisional application No. 63/478,775, filed on Jan. 6, 2023.

(51) Int. Cl. H01L 23/58; H01L 23/48; H01L 25/18; H02J 7/00; H03F 3/45

(52) U.S. Cl. CPC H01L 23/58; H01L 25/18; H03F 3/45475; H01L 23/481; H02J 7/0063

(57) ABSTRACT

A three-dimensional integrated circuit is provided. In various embodiments, the three-dimensional integrated circuit includes a first electronic module disposed on a substrate of the three-dimensional integrated circuit and a first battery disposed on the first electronic module and electronically coupled to the first electronic module. The first battery may be configured to provide power to the first electronic module. The three-dimensional integrated circuit includes a second electronic module disposed on the first battery, and a second battery disposed on the second electronic module and electronically coupled to the second electronic module. The second battery may be configured to provide power to the second electronic module.

### CROSS-REFERENCE TO RELATED APPLICATIONS

This application claims priority to and the benefit of U.S. Provisional Application Ser. No. 63/478,775, filed Jan. 6, 2023, the contents of which are incorporated by reference herein in its entirety.

### TECHNICAL FIELD

The present application relates to the technical field of batteries, for example distributed batteries in integrated circuits.

### BACKGROUND

As the demand for electronic products continues to rise, demand for advances in Integrated Circuit (IC) design and fabrication follows suit. An area of continuing advancement is providing power to the ICs. Power may be provided using external power sources. However, doing so may result in excessive noise, low efficiently, and lack of adequate power control and/or management.

Applicant has identified many technical challenges and difficulties associated with providing power to ICs. Through applied effort, ingenuity, and innovation, Applicant has solved problems related to powering ICs by developing solutions embodied in the present disclosure, which are described in detail below.

### BRIEF SUMMARY

Various embodiments described herein relate to methods, apparatuses, and systems for distributed batteries in integrated circuits.

A three-dimensional integrated circuit is provided in accordance with various embodiments of the present disclosure. In various embodiments, the three-dimensional integrated circuit includes a first electronic module disposed on a substrate of the three-dimensional integrated circuit; a first battery disposed on the first electronic module and electronically coupled to the first electronic module, wherein the first battery is configured to provide power to the first electronic module; a second electronic module disposed on the first battery; and a second battery disposed on the second electronic module and electronically coupled to the second electronic module, wherein the second battery is configured to provide power to the second electronic module.

In various embodiments, the first electronic module further includes at least one of a first processor, a first memory, a first radio frequency circuit, or first a sensor circuit and the second electronic module comprises at least one of a second processor, a second memory, a second radio frequency circuit, or a second sensor circuit.

In various embodiments, the three-dimensional integrated circuit further includes a plurality of through-silicon via (TSV) connections configured to: electronically couple the first electronic module with the second electronic module; and transfer data between the first electronic module and the second electronic module. In various embodiments, the plurality of TSV connections surround the first battery.

In various embodiments, the three-dimensional integrated circuit further includes a plurality of through-silicon via (TSV) connections configured to: electronically couple the first electronic module with the second electronic module; and transfer data between the first electronic module and the second electronic module. In various embodiments, the first battery includes a plurality of through holes and the plurality of TSV connections pass through the through holes of the first battery.

In various embodiments, the three-dimensional integrated circuit, further includes: a third battery disposed on a first side wall of the three-dimensional integrated circuit, and configured to provide power to at least one of the first or second electronic modules; a fourth battery disposed on a second side wall of the three-dimensional integrated circuit, and configured to provide power to at least one of the first or second electronic modules; a fifth battery disposed on a third side wall of the three-dimensional integrated circuit, and configured to provide power to at least one of the first or second electronic modules; and a sixth battery disposed on a fourth side wall of the three-dimensional integrated circuit, and configured to provide power to at least one of the first or second electronic modules.

In various embodiments, the first battery includes a first battery housing, the second battery includes a second battery housing, the third battery includes a third battery housing, the fourth battery includes a fourth battery housing, the fifth battery includes a fifth battery housing, and the sixth battery includes a sixth battery housing.

In various embodiments, the first, second, third, fourth, fifth, and sixth battery housings comprise a heat conductive material, and the third, fourth, fifth, and sixth battery housings are configured to: physically couple to the first and second battery housings; and transmit heat generated by the first and second electronic module from the first and second battery housings to an outside environment.

In various embodiments, the third, fourth, fifth, and sixth battery housings comprise an electromagnetic field attenuating material and are configured to reduce an external electromagnetic interference on the first and second electronic modules.

In various embodiments, a three-dimensional integrated circuit includes two or more electronic modules; two or more batteries, wherein a battery of the two or more batteries is configured to provide power to at least a corresponding electronic module of the two or more electronic modules; and two or more power deliver interfaces, wherein a power delivery interface of the two or more power delivery interfaces corresponds to the battery, and the power delivery interface includes an amplifier configured to receive an output of the battery and provide an amplified output to at least the corresponding electronic module.

In various embodiments, the amplifier is a linear amplifier and includes a power transistor configured to: receive the output of the battery at the source of the power transistor; and generate the amplified output at a drain of the power transistor.

In various embodiments, the linear amplifier includes: an operational amplifier configured to: receive a negative feedback voltage; compare the negative feedback voltage with a reference voltage, wherein the reference voltage is a bandgap voltage configured to remain independent of power variations of the battery, temperature changes, and load variations of the corresponding electronic module; generate an error output; and provide the error output to a gate of the power transistor; and a linear voltage divider, the linear voltage divider configured to: receive the amplified output from the drain of the power transistor; and generate the negative feedback voltage by linearly dividing the amplified output from the drain of the power transistor using a linearly variable resistor.

An electronic device is provided in accordance with various embodiments of the present disclosure. In various embodiments, the electronic device includes: a substrate configured to support the electronic device; an interposer electronically coupled to the substrate; a first electronic module electronically coupled to the interposer; a first battery electronically coupled to the first electronic module and configured to provide power to the first electronic module; a second electronic module configured to electronically couple to the first electronic module; a second battery electronically coupled to the second electronic module and configured to provide power to the second electronic module; a third electronic module electronically coupled to the interposer; and a third battery electronically coupled to the third electronic module and configured to provide power to the third electronic module.

In various embodiments, the first electronic module, the first battery, the second electronic module and the second battery are vertically stacked with respect to the substrate. In various embodiments, the first battery is placed between the first and second electronic modules. In various embodiments, the electronic device further includes a plurality of through-silicon via (TSV) connections configured to: electronically couple the first electronic module with the second electronic module; and transfer data between the first electronic module and the second electronic module. In various embodiments, the plurality of TSV connections surround the first battery.

In various embodiments, the electronic device further includes a plurality of through-silicon via (TSV) connections configured to: electronically couple the first electronic module with the second electronic module; and transfer data between the first electronic module and the second electronic module. In various embodiments, the first battery includes a plurality of through holes and the plurality of TSV connections pass through the through holes of the first battery.

In various embodiments, the first battery is configured to provide power to the first electronic module and the second electronic module in case of a failure of the second battery. In various embodiments, the first electronic module and the second electronic module are electronically coupled through one or more electronically connections inside the interposer.

In various embodiments, the electronic device further includes a first power delivery interface electronically coupled between the first battery and the first electronic module, wherein the power deliver interface includes a voltage regulator configured to regulate an output voltage of the first battery for the first electronic module.

In various embodiments, the electronic device further includes: a fourth electronic module electronically coupled to the second battery; and a fifth electronic module electronically coupled to the second battery and placed in a same layer with the fourth electronic module, wherein the fourth and fifth electronic modules are stacked vertically with respect to the second battery, and wherein the second battery is configured to provide power to at least one of the second, fourth, or fifth electronic modules.

The foregoing illustrative summary, as well as other exemplary objectives and/or advantages of the disclosure, and the manner in which the same are accomplished, are further explained in the following detailed description and its accompanying drawings.

### BRIEF DESCRIPTION OF THE DRAWINGS

Reference will now be made to the accompanying drawings, which are not necessarily drawn to scale, and wherein:

FIG. 1 is a schematic diagram illustrating integrated circuits, in accordance with the prior art;

FIG. 2(a)-2(b) are schematic diagrams illustrating solid state battery design, in accordance with various embodiments of the present disclosure;

FIG. 3(a) is a schematic diagram illustrating on chip battery, in accordance with the prior art;

FIG. 3(b) is a schematic diagram illustrating on chip battery, in accordance with various embodiments of the present disclosure;

FIG. 4(a)-4(b) is a schematic diagram illustrating electrical connections in an integrated circuit, in accordance with various embodiments of the present disclosure;

FIGS. 5(a)-5(h) are schematic diagrams illustrating a process for putting a battery between two layers of an integrated circuit, in accordance with various embodiments of the present disclosure;

FIG. 6 is a schematic diagram illustrating distributed batteries, in accordance with various embodiments of the present disclosure;

FIG. 7(a) is a schematic diagram illustrating on chip battery, in accordance with the prior art;

FIG. 7(b) is a schematic diagram illustrating distributed batteries, in accordance with various embodiments of the present disclosure;

FIG. 7(c) is a schematic diagram illustrating various battery models;

FIG. 7(d)-7(e) are diagrams illustrating various simulation results;

FIG. 8(a) is a schematic diagram illustrating on chip battery, in accordance with the prior art;

FIG. 8(b) is a schematic diagram illustrating distributed batteries, in accordance with various embodiments of the present disclosure;

FIG. 8(c)-8(d) are diagrams illustrating various simulation results;

FIG. 9(a) is a schematic diagram illustrating distributed batteries, in accordance with the prior art;

FIG. 9(b) is a schematic diagram illustrating distributed batteries, in accordance with various embodiments of the present disclosure;

FIG. 10(a) is a schematic diagram illustrating on chip battery, in accordance with the prior art;

FIG. 10(b) is a schematic diagram illustrating distributed batteries, in accordance with various embodiments of the present disclosure;

FIG. 10(c) is a schematic diagram illustrating different charging levels of a battery, in accordance with various embodiments of the present disclosure;

FIGS. 11(a)-11(b) are schematic diagrams illustrating circuits, in accordance with various embodiments of the present disclosure;

FIG. 12(a) is a schematic diagram illustrating on chip battery, in accordance with the prior art;

FIG. 12(b) is a schematic diagram illustrating distributed batteries, in accordance with various embodiments of the present disclosure;

FIGS. 13(a)-13(b) are schematic diagrams illustrating distributed batteries, in accordance with various embodiments of the present disclosure;

FIGS. 14(a)-14(b) are schematic diagrams illustrating distributed batteries, in accordance with various embodiments of the present disclosure;

FIG. 14(c) is a diagram illustrating various simulation results;

FIG. 15 is a diagram illustrating various simulation results; and

FIG. 16 is a schematic diagram illustrating an electronic device, in accordance with various embodiments of the present disclosure.

### DETAILED DESCRIPTION

The present disclosure more fully describes various embodiments with reference to the accompanying drawings. Some, but not all, embodiments are shown and described herein. Indeed, the embodiments may take many different forms, and accordingly, this disclosure should not be construed as limited to the embodiments set forth herein. Rather, these embodiments are provided so that this disclosure will satisfy applicable legal requirements. Like numbers refer to like elements throughout.

The phrases “in an example embodiment,” “some embodiments,” “various embodiments,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such components or features may be optionally included in some embodiments, or may be excluded.

The terms “electronically coupled” or “in electronic communication with” in the present disclosure refer to two or more electrical elements (for example, but not limited to, a controller, infrared camera, filter, an example processing circuitry, communication module, input/output module, memory) and/or electric circuit(s) being connected through wired means (for example but not limited to, conductive wires or traces) and/or wireless means (for example but not limited to, wireless network, electromagnetic field), such that data and/or information (for example, electronic indications, signals) may be transmitted to and/or received from the electrical elements and/or electric circuit(s) that are electronically coupled.

The term “mechanically coupled” in the present disclosure refers to two or more mechanical elements (for example, but not limited to, a frame, a surface, a support unit, a joint, etc.) being physically connected in various ways such as directly, through intermediary elements, and/or using fastener(s), clasps, clamps, joints, pin joint, axle, hinge, adhesive, etc. The term “mechanically coupled” may refer to any of movable, turntable, swiveling, pivoting, fixed, and/or stationary, etc.

### System Overview

Some methods of improving digital system energy efficiency through silicon CMOS scaling may face more and more challenging. Therefore, methods and techniques such as 2.5D and 3D integration may be used which demonstrate continual applicability of Moore's law. High demand for portable consumer electronics has impacted the portable energy industry. Combining on-chip batteries with heterogeneous 3D ICs may provide further miniaturization of point of loads (POLs).

These 3D ICs could be powered by conventional macroscopic power sources, however doing so may result in interconnection problems, noise, and problems with power control. To solve such technical problems, various embodiments of the present disclosure provide distributed batteries in 3D integrated circuits. In various embodiments of the present disclosure, a plurality of smaller batteries with different voltage levels and specifications are used in place of one larger battery.

Further, energy efficiency in digital systems may face challenges due to the constraints imposed by small-scale transistors. Moreover, the growing demand for portable consumer electronics necessitates the use of compact energy sources. To address these challenges, heterogeneous 3D IC technology has been used.

Various approaches for enhancing digital system energy efficiency through silicon CMOS scaling may get increasingly difficult. Factors such as the inherent physical size constraint, complexity, and manufacturability of miniature transistors, and/or the negative consequences of cost and yield for creating miniature transistors may be among the most prohibitive. As a result, methods and techniques are needed to indicate the applicability and/or validity of Moore's law.

In various embodiments, distributed batteries within a heterogeneous 3D IC are provided. Various embodiments of the present disclosure provide utilizing multiple distributed small batteries which may have different specifications among different modules of 3D ICs. This approach may for example optimize performance and overcome limitations associated with both 3D ICs and conventional power delivery methods.

Distributed batteries may also for example provide an effective management of the heat generated by energy sources and modules within a 3D IC. Furthermore, they may contribute to achieving a uniform distribution of heat throughout the entire structure, which ultimately may provide the optimal performance of the batteries and modules. Various embodiments of the present disclosure are tested using simulation results that indicate up to approximately 40 percent enhancement in achieving a more even distribution of generated heat. Additionally, the proposed distributed battery techniques improve power delivery, enhance reliability, and enable optimized voltage regulation while improving efficiency. Additionally, various alternative configurations provided by various embodiments of the present disclosure offer extra energy storage capacity and provide efficient electromagnetic shields, resulting in a notable reduction of external electromagnetic noises by up to approximately 60 dB.

In various embodiments, on-chip batteries as distributed energy sources are used in heterogeneous 2.5d/3d integrated circuits. For example, 3D integration, in which circuits are stacked vertically on top of one another are provided. In comparison to planar 2D ICs, 3D integration of ICs may overcome the constraints of processing methods. For example, vertical stacking of functional dies allows for considerable improvements in speed, power efficiency, latency, and form factor.

3D ICs may be manufactured using methods such as at least one of chip stacking, wafer stacking, or full monolithic stacking. 3D IC integration technologies may span from substrate package level system integration to wafer level system integration (WLSI), which may go beyond Moore's Law.

Heterogeneous IC, as used in various embodiments herein, may refer to the integration of separate manufactured components such as logic, memory, analog-mixed circuits, and RF circuits into a higher-level assembly or system in package (SiP). This technology may enhance the system's functionality and operating characteristics. This technique has made it possible to combine chiplets from several manufacturing process flows into a single package with a range of functions. The primary motivations for heterogeneous integration technology adoption have been improvements related to power usage, performance, area, and cost. Sensor integration is another motivation for 3D heterogeneous integration. The system integration of sensors with ICs and passive components is becoming increasingly important, particularly in area of distributed wireless sensor systems.

As previously discussed, the aspiration for enhanced energy efficiency in digital systems through silicon CMOS scaling may encounter difficulties owing to the inherent limitations in the physical size, complexity, and manufacturability of small-scale transistors. Additionally, the increased costs and lower yield associated with producing miniature transistors may pose obstacles. To address this technical challenge, 3D integration has been used as a promising solution, involving the vertical stacking of smaller, low-cost, high-yield dies. This approach may provide benefits such as improvements in input/output (I/O) bandwidth, energy efficiency, latency, and form factor. Heterogeneous ICs, which combine discrete modules or chiplets (such as logic, memory, mixed-signal circuits, and RF circuits) into a single SiP, may enhance system functionality. The integration of ICs with sensors and passive components may also be desirable in distributed wireless sensor networks.

Along with improvements in 3D ICs, the worldwide need for portable consumer electronics has increased the demand for miniature energy sources. For example, miniature sensing and computing nodes may be used in intelligent medical implants or the Internet of Things (IOT). Such small autonomous devices may be wireless, which means they need to be energy autonomous, i.e., include their own energy sources.

Large-scale energy sources may be used to energize groups of sensors and actuators, but this approach results in difficulties with interconnection, noise, and voltage regulation. By designing the energy source to be commensurate in size with the sensors and actuators, the intricacies involved in the process of delivering power are mitigated. Thus, the efficiency and operating lifetime of autonomous devices can be improved by incorporating miniaturized energy storage elements such as micro-batteries. Since planar 2D battery cells may have inherent energy density restrictions, the implementation of 3D micro-structures is promising for improving micro-battery technology. The development of 3D solid-state batteries (SSBs) has accordingly been driven by the goal of enhanced energy density. Micro-batteries employing such 3D structures may provide high energy and power densities after attachment to planar surfaces.

Obtaining access to a high-quality power source is important prerequisite for both 2D and 3D ICs. The integration of on-chip micro-batteries with heterogeneous 3D ICs may provide for high miniaturization of the point-of-load (POL) DC-DC converters used to generate such power sources. The use of on-chip batteries may for example 1) improve the efficiency of such converters by eliminating the parasitic impedance of the package and board-level traces, and 2) simplify the development of on-chip power distribution networks for supplying multiple voltage domains.

In various embodiments, various technical solutions are provided to overcome the technical challenges in providing efficient power to ICs, such as heterogeneous 2.5D/3D ICs. Various embodiments provide distributed batteries in the 2.5D or 3D IC structure, to for example leverage the potential benefits that on-chip batteries offer.

Referring now to FIG. 1, a schematic diagram illustrating extended-Cube (X-Cube) silicon-proven 3D IC packaging technique is provided in accordance with the prior art. The X-Cube may be used in technology nodes.

The X-Cube is a version of 3D IC wafer level integration. Through-Silicon Via (TSV) technology may be used in the 7 nm X-Cube test chip to stack an SRAM on top of a logic die, freeing up room to pack more memory into a smaller footprint. The ultra-thin package design, made possible by 3D integration, may have shorter signal lines between the dies for increased data transfer speed and energy efficiency.

For example, in X-Cube, 7 nm technology node may be used to stack SRAM on top of a logic die. The structure receives its power externally, which may have problems such as high noise. Some on-chip batteries may solve issues like noise, power loss, and the complexity of power delivery. However, the on-chip battery as used in the prior art may add problems such as increasing the temperature locally in the 3D IC. The on-chip batteries provided in the prior art may also face premature death.

A 3D chiplet architecture, however, may be used in high-performance computing products. For example, the chiplet architecture may be used in attaching a 3D vertical cache onto a processor. The 3D chiplet architecture may provide more than 200 times the interconnect density of 2D chiplets and more than 15 times the density compared to simple vertical stacking systems.

System on Integrated Chip (SoIC) technology is another approach which may enable system expansion at a lower cost and with higher performance by executing SoC partitioning and re-integration via the stacking of I/O logic and core circuits chips.

SoIC may also enable the design and integration of heterogeneous chips in a variety of technology nodes, materials, functionalities, and chip sizes, resulting in a 3D IC. Technology node may refer to the physical size of the transistor—e.g the smaller the transistors, the more transistors may be placed in the same area, the faster they switch, the less energy they require and the cooler the chip runs. This SoIC technology may provide high power and signal integrity, as well as substantially lower communication latency and more than 20 Tbps memory bandwidth to accommodate computing applications.

As previously described, along with improvements in 3D ICs, the need for portable consumer electronics has had a significant impact on the portable energy industry. Attempts have been made to produce miniature wireless devices that can be used in micro-electromechanical systems (MEMS), smart medical implants and specially IoT devices. A characteristic of small autonomous devices is that they operate wirelessly, which implies that they need electricity onboard. Traditional macroscopic power sources may be used to power arrays of micromachined sensors and actuators, but it may cause interconnection issues, noise, and challenges controlling the amount of power given. Alternatively, designing the power supply to be of the same size as the sensors and actuators reduces the complexity of power delivery.

Various embodiments of the present disclosure remove the external circuitry for powering different modules with different voltage levels inside the 3D IC and turn it to an autonomous device. With a small energy consumption, autonomous devices can integrate electricity storage devices to make them highly efficient. As devices become smaller, assembling them from their individual components becomes more difficult. There are inherent power limitations in planar 2D cells, and the introduction of 3D microarchitectures may provide for improvements in micro-battery technology. Three-dimensional Solid-State Batteries (SSBs) may increase the cell's energy. With 3D architectures, surface mountable batteries may offer a significant increase in power and energy per footprint.

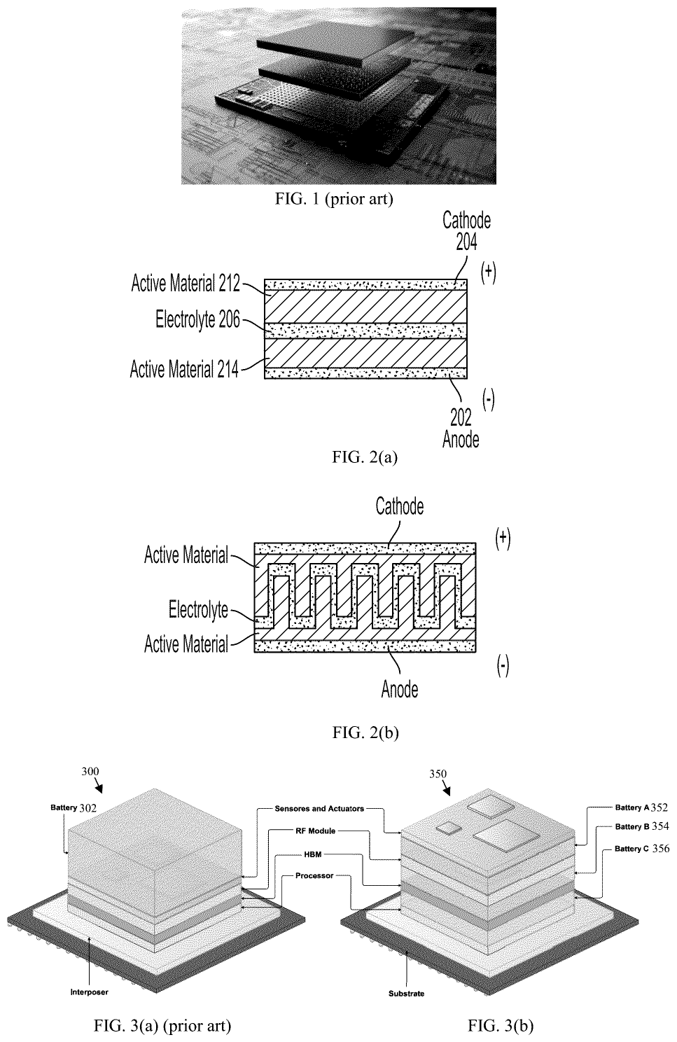

Referring now to FIG. 2(a) and FIG. 2(b), schematic diagrams illustrating 2D and 3D SSBs respectively, are provided in accordance with various embodiments of the present disclosure. FIG. 2(a) illustrates 2D SSBs that are made by sequentially layering cathode 204, a first active material layer 212, solid electrolyte 206, a second active material layer 214, and anode 202. FIG. 2(b) illustrates 3D SSBs that may increase cell's energy density by creating indents in the layers, in accordance with various embodiments of the present disclosure.

In accordance with various embodiments, a combination of on-chip batteries and heterogeneous 3D ICs, which incorporate a variety of modules such as processors, memory, control circuits, RF circuits, hardware security section and passive devices, may provide miniaturization of the POL.

A requirement of integrated circuits (ICs) is the delivery of a high-quality power source with minimal energy loss. In various embodiments, the parasitic impedance of the board and package may be removed with the aid of on-chip battery, which is crucial for low power designs. While off-chip power supplies have advanced, they are not always suitable for heterogeneous 3D ICs. When power supplies for a large number of modules need to be individually controlled, using off-chip converters can result in significant overhead. Off-chip power supply configurations may require separate DC-DC converters for each module or there may be an overhead in the number of supply pins for the heterogeneous 3D IC. This can make global power grid distribution quite tricky. To enhance the quality of the power delivered inside the ICs, various embodiments of the present disclosure provide an on-chip power supply system with numerous converters to provide multiple voltage domains.

Various embodiments of the present disclosure boost the efficiency and power density of on-chip batteries as a function of area. These batteries may need to be able to supply sufficient current to high number of transistors, for example in order of billions. When dealing with heterogeneous ICs that include various modules, the supply power and/or current requirement for the batterie increases. Various embodiments address these concerns, issues and provide technical solutions to improve power and/or current production of on-chip batteries. A requirement for heterogeneous ICs is the delivery of high-quality power to the on-chip modules while minimizing energy loss. In various embodiments of the present disclosure, high-quality power delivery systems are provided that dissipate low amount of energy. In various embodiments, the power loss is reduced so that the structure temperature does not rise due to the internal resistance of VDD and GND rails.

Referring now to FIG. 3(a), a schematic diagram 300 illustrating an on-chip battery is provided in accordance with the prior art. As shown in FIG. 3(a) a large unregulated DC voltage may be produced by the battery 302 and the voltage may be stepped down and regulated inside the power delivery system to provide adequate power for each module. Resources for power regulation and conversion should be effectively managed and it may be challenging to provide high quality power with minimal energy losses across a variety of on-chip voltage domains. Other problems and challenges with this type of power distribution method may include imbalanced heat generation, noise, power loss, reliability, complexity, shorter lifecycles for the battery and/or the IC as they otherwise may have, etc.

Various embodiments of the present disclosure overcome these and/or other technical challenges by using distributed batteries in 3D heterogeneous integrated circuits. Referring now to FIG. 3(b), a schematic diagram 350 illustrating distributed batteries in an integrated circuit is provided in accordance with various embodiments of the present disclosure.

In various embodiments, multiple smaller batteries with various voltage levels and/or specifications are used instead of one larger battery inside a heterogeneous 3D IC. For example, a distinct battery is placed near each module. In an example illustrated by FIG. 3(b), battery A (e.g. referred to as a first battery 352) is placed in proximity to and may provide power to RF module (e.g. referred to as a second functional module). In an example embodiment, battery B (e.g. referred to as a second battery 354) is placed in proximity to and may provide power to a High Bandwidth Memory (HBM) (e.g. referred to as a third functional module). In an example embodiment, battery C (e.g. battery 356) is placed in proximity to and may provide power to a processor layer (e.g. referred to as a fourth functional module).

In various embodiments, each of the batteries may have its own unique characteristics. For example, they can supply varying voltage levels and output different currents for various loads. These batteries may be manufactured using various technologies and chemistry to provide an optimized performance tailored for a certain module they provide power to. For example, these batteries can be classified as heterogeneous batteries.

Placing batteries between modules may, however, act as a barrier to data transfer between upper and lower modules. Various embodiments of the present disclosure provide data transfer between layers while using distributed and/or heterogenous batteries. The solution provided by various embodiments of the present disclosure do not increase the complexity or negate the advantages of 3D ICs.

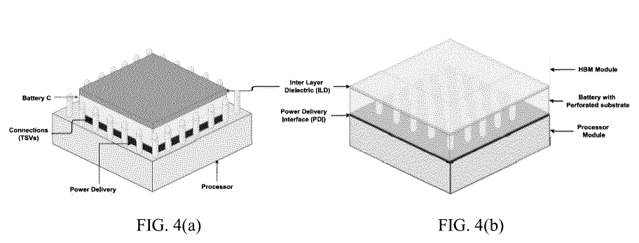

FIG. 4(a) is a schematic diagram illustrating connections in an IC in accordance with various embodiments. In various embodiments, all the through-silicon vias (TSVs) and other connections between upper and lower modules are located outside the battery area, as for example shown by FIG. 4(a). For example, as illustrated by FIG. 4(a), all the connections between a higher module layer and a lower module layer are pushed to the edges, with the battery in the center. Using this technique, various embodiments preserve battery integrity while making battery manufacturing easier because this technique may make it simple to incorporate the battery and may reduce the density of inter-module connections.

In various embodiments, one or more perforated substrates may be used to create connections between upper and lower module layers with a SSB in between, for example by using a battery with perforated substrate. For example, multichannel plate substrates may be used to build 3-D thin-film micro-batteries. In various embodiments, “through holes” are put in the battery substrate to increase the surface area and thus raise the power density and energy density at the same time. In accordance with various embodiments, using a perforated substrate instead of a full substrate provides gaining a significant amount of geometrical area for film deposition. The added area for each cylindrical hole can be calculated for example by Eqn. (1).

$$AG = \frac{π . d}{{( d + s )}^{2}} ( t - \frac{d}{2} ) + 2 \qquad Eqn . ( 1 )$$

In Eqn. (1), AG is the area gain, s is the inter-channel spacing, d is the microchannel diameter, and t is the substrate thickness. The TSVs can be routed through these through holes to connect higher and lower modules. As an example, for a perforated substrate with a d=50 μm, s=10 μm and t=500 μm, the active surface area gain is approximately 23. FIG. 4(b) is a schematic diagram illustrating the positioning of TSVs and other type of connections, inside the battery with perforated substrate.

In various embodiments, it is desirable that the battery fabrication process works with standard Si semiconductor technology. Therefore, in various embodiments, the substrate of SSB is made from silicon. This silicon substrate may only act as a structural support. Therefore, it is desirable to use an interlayer barrier, such as TiN, Pt, SiO2, or Al2O3 between battery substrate and other integrated electronic devices to prevent any injection of Li ions into the rest of the structure and other modules. In various embodiments, on 3D Si-based substrates, battery components are deposited using any of Atomic Layer Deposition (ALD), Chemical Vapor Deposition (CVD), and sputtering techniques.

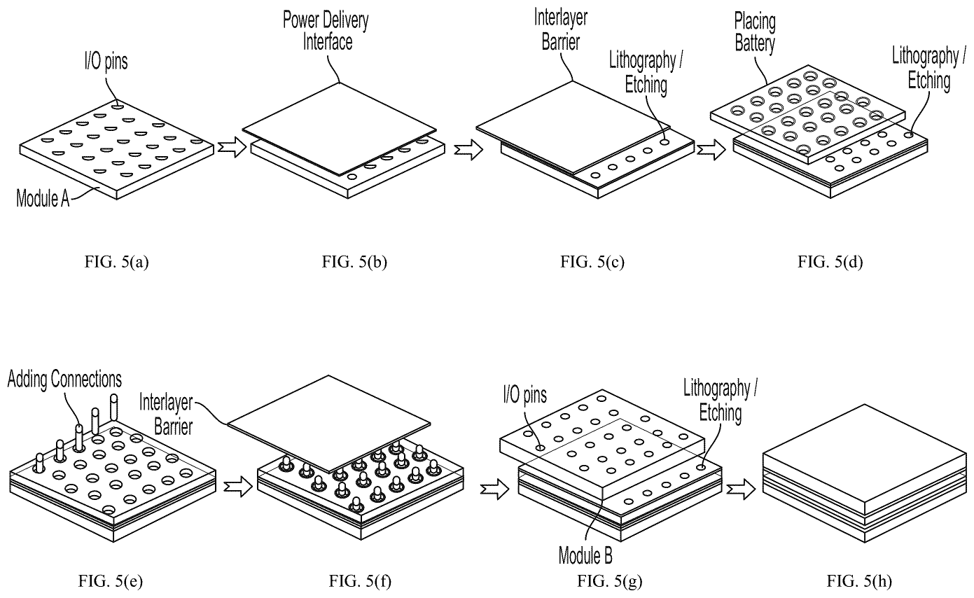

Referring now to FIG. 5(a) to FIG. 5(h) a schematic diagram illustrating the process flow for putting a battery between two different modules is provided in accordance with various embodiments of the present disclosure. For illustration purposes, to simplify the overall structure and better demonstrate other concepts, the position of TSVs and connections is not presented in the following description and figures. However, various embodiments described herein may include the interlayer barriers as illustrated by FIG. 5(a) to FIG. 5(h).

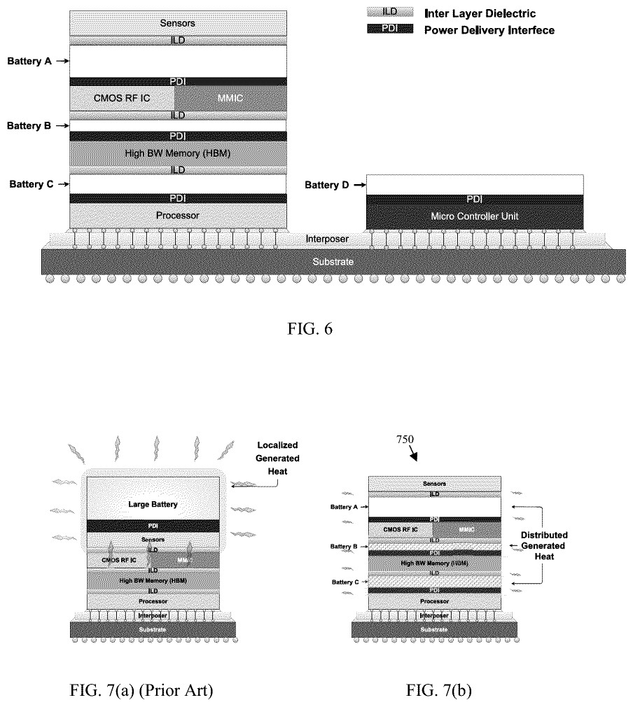

In accordance with various embodiments, FIG. 5(a), illustrates placing or fabricating module A (e.g. a first module) of a 3D IC with its I/O pins. For example module A may be fabricated on a substrate of the 3D IC. FIG. 5(b) illustrates placing the power delivery interface (PDI) on top of the module A. FIG. 5(c) illustrates opening I/O pin locations on the PDI for example using lithography or etching techniques, and depositing an interlayer barrier (ILB) on top of the PDI. FIG. 5(d) illustrates opening I/O pin locations on the ILB and placing the battery with the perforated substrate. FIG. 5(e) illustrates adding connections inside through holes of battery with perforated substrate. FIG. 5(f) illustrates depositing another ILB. FIG. 5(g) illustrates opening connection locations on the other ILB using lithography or etching techniques and placing or fabricating module B (e.g a second module) on top of the other ILB. FIG. 5(h) illustrates a structure with a battery between two modules A and B and other layers as described above. In various embodiments, any number of more layers and/or modules as described above may be added as for example illustrates by FIG. 6.

In various embodiments, two or more active semiconductor chips may be put side by side on a silicon interposer in a 2.5D packaging to achieve very high die-to-die connection density. Devices may be manufactured separately and delivered bare dies to the assembly house. Such smaller dies may be accommodated on the interposer, which in a sense is large bare die. In various embodiments, in addition to connecting the devices to one another and to the outside world, the interposer may incorporate TSVs to carry signals through the substrate. In various embodiments, devices are installed on both top and bottom surfaces of some interposers. Similar to 3D ICs, 2.5D assemblies may use shorter connections to conserve power.

2.5D and 3D IC packaging may have important roles in applications such as CPU, mobile AP, Si photonics, display driver IC, etc. 2.5D and 3D ICs may be suitable transistor scaling solutions for maintaining Moore's law. The combination of 2.5D and 3D is advantageous in many applications. Referring now to FIG. 6, a schematic diagram illustrating that the techniques according to various embodiments of the present disclosure can be integrated with any 2.5D, 3D, or a combination of 2.5D and 3D types of packaging. In various embodiments, distributed batteries may be utilized to power any of 2.5D and 3D integrated circuits or a combination of 2.5D and 3D integrated circuits.

Various embodiments herein provide:
Systems and methods for spreading the heat produced by the operational battery (charging/discharging) inside heterogeneous integrated circuits equally throughout the entire structure and preventing any hot spots inside the IC.
Systems and methods for addressing the thermal problem and minimizing the adverse impacts of heat generated by neighboring modules on a single module.
Systems and methods for lessening the local stress on modules due to presence of hot spots.
Systems and methods for reducing and/or stopping energy loss caused by voltage domain conversion.
Systems and methods for streamlining the Power Delivery Network (PDN), particularly for heterogeneous ICs that need a wide range of voltage domains.
Systems and methods for providing each module with less noisy VDD and GND, for example due to providing shorter connections.
Systems and methods for increasing reliability and robustness of 3D ICs for crucial and critical applications.
Systems and methods for prolonging battery life and preventing battery from premature death.
Systems and methods for stopping the die area on each heterogeneous IC module from increasing because of PDN simplification.
Systems and methods for facilitating supercharging and neck-breaking acceleration.
Systems and methods for assisting in lowering the cost of battery manufacturing for heterogeneous ICs.
Systems and methods for lowering the size and form factor of the final structure by utilizing unallocated space inside the 3D ICs.

The following terms or corresponding acronyms are referred to in the various parts of the present disclosure to describe the relevant technology in detail:
3D IC—3 Dimension Integrated Circuit
EDP—Energy-Delay-Product
TSV—Through-Silicon Via
SoIC—System on Integrated Chip
CMOS—Complementary Metal-Oxide-Semiconductor
MEMS—Micro-Electro-Mechanical Systems
IoT—Internet of Things
SSB—Solid-State Battery
POL—Point of Load
PDN—Power Distribution Network
PA—Power Amplifier
HBM—High Bandwidth Memory
MIMO—Multi Input Multi Output
ALD—Atomic Layer Deposition
CVD—Chemical Vapor Deposition
MMIC—Monolithic Microwave Integrated Circuits
RFIC—Radio Frequency Integrated Circuits
LDO—Low Drop Out dc-dc regulator

### Description of the Technology

### Heat Management: Heat Generation and Mitigation

An occurrence that may lead to a decrease in system performance in heterogeneous ICs is the production of heat by various modules. Heat may be generated not only by components such as power amplifiers and processors but also by on-chip batteries, which may exacerbate the problem. For example, during charging and discharging cycles, a battery produces heat due to internal electrochemical reactions and charge transport processes. The rate at which heat is generated depends on factors such as internal resistance, charging/discharging rate, and cell temperature. Inefficient dissipation of the heat may be due to internal electrochemical reactions and charge transport processes. Inefficient dissipation of the heat generated can cause the cell temperature to rise, leading to reduced battery performance and enhanced degradation of the electrodes and/or electrolyte.

Therefore, efficient heat management is desirable to maintain optimal battery performance and prevent damage. Given the requirement for a battery to supply significant current to various sections and modules in a heterogeneous IC, it is anticipated that a substantial amount of heat will be produced in and around the battery. Due to the localized heat generated in one area, a specific volume of the 3D IC will experience elevated temperature(s). The high heat density resulting from confinement within a small volume may pose a challenge for conventional heat transfer techniques to dissipate it externally. Additionally, mechanical stress and dimensional changes may result from such localized heating.

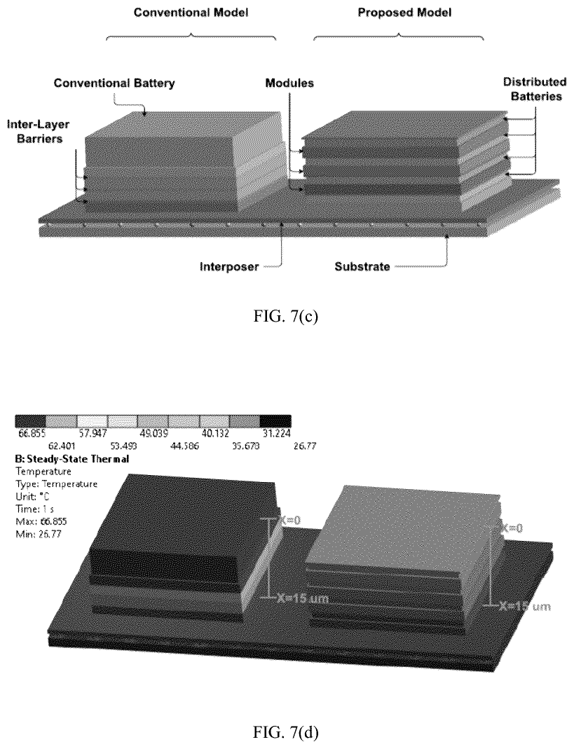

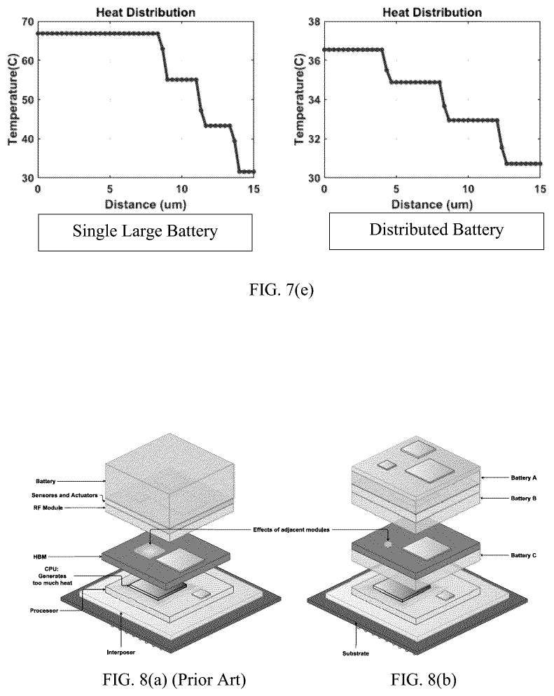

Therefore, controlling battery temperature is desirable for both safe operation and a long lifespan. The surface area to volume ratio of a battery decreases with size, thus making it difficult to maintain a uniform and controlled temperature across all the components of a large battery. For example, in the situation where a single large battery energizes all the modules of a heterogeneous 3D IC, such a battery has to supply the entire load current of the 3D stack, resulting in the generation of a significant amount of internal heat that cannot be efficiently transferred to the environment. The result may be a localized hotspot, as shown in FIG. 7(a). By contrast, the proposed distributed batteries concept as provided by various embodiments of the present disclosure, suggests using one battery per module, resulting in much lower current demand for each battery and less heat generated per unit area. Furthermore, the generated heat will be more evenly dispersed throughout the 3D IC structure, thus avoiding the generation of hotspots, as illustrated by FIG. 7(b).

In various embodiments, to facilitate a direct comparison of thermal performance between the conventional and proposed approaches, a geometry that integrates both ideas on a single interposer is provided, as shown in FIG. 7(c). Doing so provides for evaluating the benefits of the proposed approach and identifying any issues that need to be addressed to optimize its performance.

Referring now FIG. 7(d), thermal simulation results of 3D IC structures using conventional (left) and distributed (right) batteries are provided. For this simulation, as an example, the large battery supplies 100 mA to power the entire 3D stack, which matches its capacity (assumed to be 100 mAh). On the other hand, each battery in the proposed distributed battery model in accordance with various embodiments of the present disclosure, supplies only one module, resulting in much lower output current; however, the sum of all these currents is equal to 100 mA. Therefore, In various embodiments, the sum of the energy outputs of the batteries in the distributed model is equal to the energy requirement of all the respective distributed modules.

Analysis System (ANSYS) software was utilized to simulate the resulting temperature distribution. FIG. 7(d) provides simulation results which show a much more uniform thermal distribution for the distributed battery structure as expected. This difference is evident even more clearly in FIG. 7(e), which shows the simulated temperature along the vertical (x) axis through one edge of the 3D stack. Note that the temperature of the substrate was set to a fixed value of 27° ° C. (modeling a perfect heat sink) in both cases and convection was neglected.

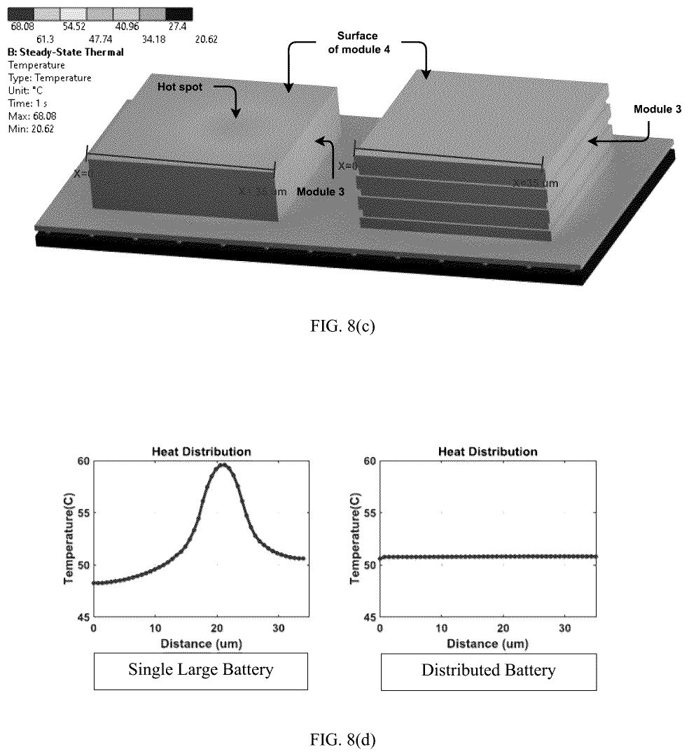

Certain components within 3D ICs, such as power amplifiers and processors, may be particularly power-hungry and thus may generate a significant amount of heat. These components can generate additional hotspots within the 3D structure that may impact nearby modules. One issue caused by such hotspots is physical strain resulting from thermal expansion. This problem is illustrated in FIG. 8(a). The use of distributed batteries, in accordance with various embodiments of the present disclosure, can significantly reduce this problem since individual battery module may act as thermal buffers that hinder the formation of hotspots, as shown in FIG. 8(b). For example, if a GPU produces too much heat, in the conventional approach, an adjacent module may suffer from a large hot spot generated by the GPU. However, when using distributed batteries in accordance with various embodiments of the present disclosure, the hot spot may become much smaller and the adverse effect on the neighboring module may significantly reduce.

The qualitative advantages mentioned above are quantified using a thermal simulation of the same geometry as illustrated in FIG. 8(c). However, in this case, only a single die (within module #3) was assumed to dissipate energy, thus acting as a localized heat source. FIG. 8(d) illustrates that the use of a distributed battery may largely reduce both the hotspot and its impact on neighboring modules. In both cases, the temperature is measured along a path between two opposing edges in the surface of a top module. The single battery case results in a hotspot with a maximum temperature rise of ˜15°, while the distributed battery case results in an almost uniform temperature distribution with a rise of only ˜5° C.

### Noise and Power Loss Mitigation

In 3D ICs, as different modules are stacked on top of one another, their distance from the battery varies. As a result, modules located far from the battery may use larger wires and connections to the battery, resulting in greater resistance, inductance, and capacitance. Resistive noise is produced because of the internal electrical resistance which means for farther modules from battery, the amount of resistive noise is higher. As a result, it may be desirable to lower the target impedance of the power distribution network. These parasitic elements cause a voltage drop along the path of the VDD and GND rails.

Additionally, switching-intensive modules like processors, memory, and so forth may add significant switching noise to VDD and GND and turn them to dirty supply nodes. To overcome this problem, decoupling capacitors may be allocated near noisy functional modules, which may add to die area and cost. For a chip to function properly, this noise and voltage drop need be reduced significantly through the entire power delivery network (PDN).

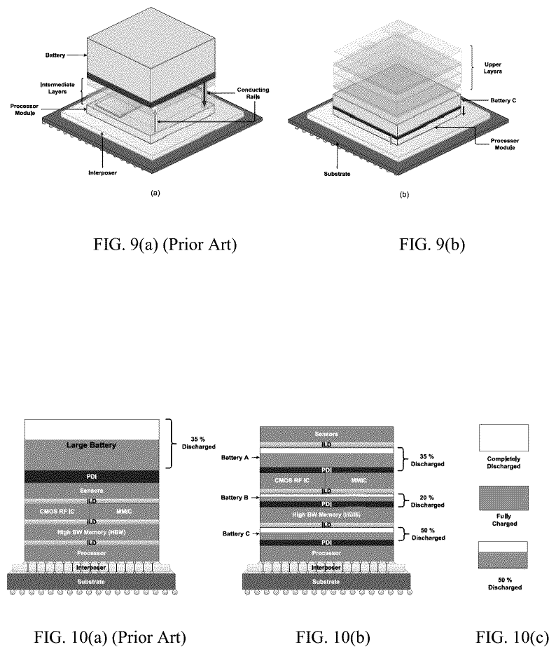

FIG. 9(a) is a schematic diagram illustrating a power supply with conventional on-chip battery using relatively lengthy trances and/or connections in accordance with the prior art. This approach in accordance with the prior art may cause significant noise and/or power loss in PDN which is not desirable particularly when it is used to feed power to a noise sensitive module, such as Processor module. These noises typically originate in the VDD and GND rails' parasitic resistance and inductance. Longer rails may cause the system to be noisier. As a result, it may be necessary for the distance between the power supply and the module to be as short as feasible.

FIG. 9(b) is a schematic diagram illustrating distributed batteries that may be used to reduce the noise issue in the VDD and GND rails, in accordance with various embodiments of the present disclosure. In various embodiments, each module may have its own power source. This aids in preventing noise generated by each module from reaching adjacent modules. Another technical advantage of the distributed batteries for heterogeneous 3D ICs in accordance with various embodiments of the present disclosure is that the generated noise from switching modules, such as multiprocessor modules, cannot easily find a way to noise-sensitive modules, such as RF modules.

By using the distributed batteries in accordance with various embodiments of the present disclosure, the need for decoupling capacitors can be reduced by using shorter connections within the PDN, leading to proportionally smaller resistance and inductance. Distributed batteries are beneficial for this purpose, as shown in FIG. 9(b). The resulting PDN may significantly reduce connection lengths, and thus voltage drops. The smaller area of the connection lengths or power supply loops also results in significant decreases in radiated EMI. Additionally, the distributed nature of the PDN increases isolation between the modules, which in turn limits the propagation of switching noise from noisy modules (such as processors) to sensitive ones (such as RF transceivers).

### Reliability

Reliability issues may become a concern if power is moved from an off-chip to an on-chip source. Any module inside a heterogeneous IC may have a specified task to perform. For example, the hardware security section module may be configured to defend the entire IC against attacks. For example, the processor module may be configured to process data. For example, the RF module may communicate processed data to the outside. If the battery, in a single battery structure according to the prior art, has a fault or malfunctions, the entire structure will collapse and shut down because there is no other power source.

It is desirable to provide reliable power to the integrated circuit system. For example, in a smart medical device that performs continuous monitoring of some crucial parameters, it is highly important to provide reliable and uninterrupted power to the device. To provide continuous power to the integrated circuit structure, it is important to have a reliable and on demand power supply. It may also be desirable to use a power distribution system, that in case of any malfunction in the battery, provide power for the most important module(s).

Various embodiments herein overcome these technical challenges of power reliability using the distributed battery systems. In accordance with various embodiments, in systems that need continuous operation or need to be powered for a specific period, PDN may be set up in a way that in the event of a problem or malfunction in power source of one specific crucial module, the battery of another module acts as a backup and provides the required power to the specific crucial module. Further, the PDN may be configured to provide extra current when a module requires more power in each situation than it normally does, by additionally connecting one or more other batteries, or all other batteries, with comparable characteristics in parallel. In various embodiments, distributed batteries and smart PDNs may work together to create an effective and reliable power source for 3D heterogeneous ICs.

### Increasing Reliability and Reducing Premature Battery Death

Reliability of the power supply is important for various applications such as wireless and/or autonomous operation since no other energy sources are likely to be available. Using distributed batteries can improve reliability by providing redundancy to localized failures and/or unexpected increases in the power requirements of particular modules. In addition, the use of distributed batteries can prolong battery lifetime by limiting discharge rates and internal heat generation.

Two important factors when considering battery functionality are battery life and battery lifespan. The first one determines how long a 3D IC can operate before needing to be recharged, and the latter is the time between the first use and replacement of the battery. Since replacing the battery inside a heterogeneous IC may be somewhat impractical, it is desirable to have a battery or system of batteries with a respectable lifespan.

FIG. 10(a) is a schematic diagram illustrating a single battery powering various other modules in accordance with the prior art. When all modules of a 3D IC are operating and relying in a single battery, the battery may be drawn to its maximum capacity. When the current increases, the battery can experience high temperatures, causing significant damage and reducing its lifespan. Therefore, using one large battery for powering the IC may put the battery under much stress and lead to its early demise. Therefore, a solution is desirable to provide an operational battery with long life and to reduce the battery's rate of degradation.

Referring now to FIG. 10(b), a schematic diagram for distributed batteries is illustrated in accordance with various embodiments of the present disclosure. In various embodiments, the distributed battery system provides for distributing the discharge strain equally among all the batteries. FIG. 10(c) is a schematic diagram illustrating a discharge level for an example battery, in accordance with various embodiments of the present disclosure. In various embodiments, during high power demand situations, the discharge strain is divided equally among each of the batteries. Therefore, instead of a single large battery that would have been under a lot of strain and eventually may suffer from premature death, a plurality of smaller batteries is used, in accordance with various embodiments herein.

Another technical advantage provided by the embodiments herein using distributed batteries is supercharging. Instead of using a single huge battery with a small peak current per pouch, a distributed battery system can distribute the electrical current demand among each distributed battery, therefore increase the speed of charging for the overall distributed battery system. Therefore, a system according to various embodiments herein is capable of supercharging, neck-breaking acceleration, and maintaining the appropriate temperature while using less space. For example, the neck-breaking acceleration may illustrate the idea that PDN can be configured to provide the appropriate amount of current for any task or performance level required by a module and/or a layer. For example, it may be necessary to make a processor work twice as fast. As a result, PDN can parallel similar batteries to provide the necessary current in such situations.

### Optimization and Voltage Regulation in PDN

Each module in a heterogeneous 3D IC, may be manufactured by a different foundry or built using a different technological node. Therefore, each module may require its own specific power supply, power level, voltage, current, etc. For example, a first functional module (e.g. the processor module) may operate at a first voltage level (e.g. 3.3 volts) while a second functional module (e.g. the RF section module) may operate at a second voltage level (e.g. 5 volts), etc. Due to the high complexity of these integrated circuits, innovative design methodologies are required to meet the stringent noise and power constraints. Therefore, to achieve point-of-load voltage delivery, various embodiments of the present disclosure use several linear or switching voltage regulators, with fast load regulation for different voltage domains.

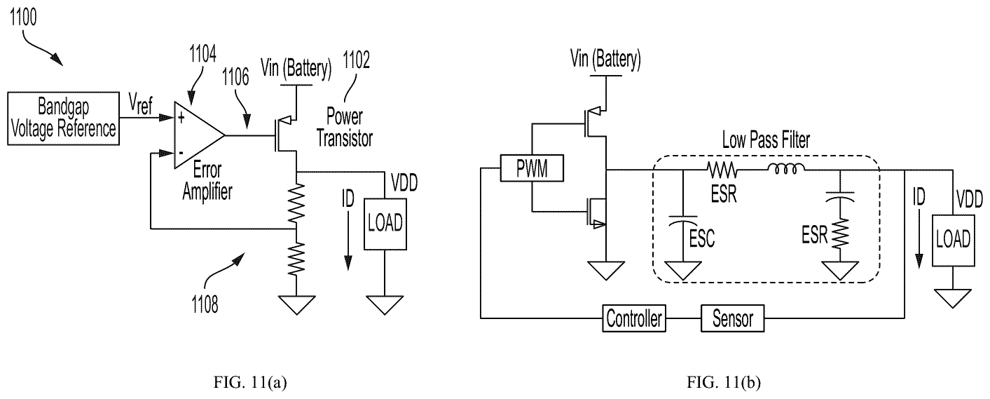

FIGS. 11(a) and 11(b) are schematic diagrams illustrating voltage regulators. In various embodiments, the voltage regulators illustrated by FIGS. 11(a) and (b), may increase die area and complexity when having high loads. For each stage or module, they use passive components and switching circuitry to supply the required voltage. It is desirable to simplify voltage regulation, particularly in the context of heterogeneous ICs.

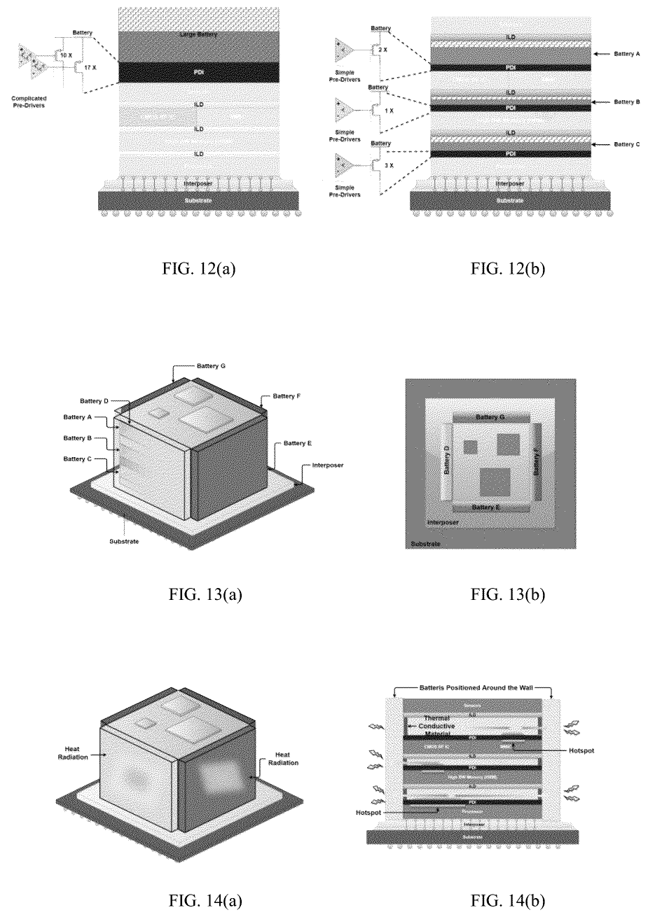

An on-chip battery may be required to power the billions of current loads inside the tens of on-chip voltage domains with sufficient, high-quality regulated current. Consequently, a complex voltage regulator system may be required to address this issue. FIG. 12(a) is a schematic diagram illustrating voltage regulator for a single on chip battery. A 3D heterogenous IC may use a Low Drop Out dc-dc regulator (LDO) to supply enough current to several modules with same VDD. A linear voltage regulator's die area may be determined by the size of output power transistor. This size, according to Eqn. (2), may be determined by the output current that each module should get from the LDO.

$${A}_{Linear} \approx α . W . {L}_{min} = α . \frac{{I}_{DD} . {l}_{min}^{2}}{{μ}_{p} {{C}_{OX} ( {V}_{IN} - {V}_{th} )}^{2}} \qquad Eqn . 2$$

Where in this equation, Vth is the MOSFET threshold voltage, Imin is the minimum channel length, α is the transistor Area to Wlmin ratio, μp is the hole mobility, and Cox is the gate oxide capacitance. According to this equation, a larger current may imply a larger transistor, which makes the pre-driver bigger and more complicated.

The distributed batteries in accordance with the embodiments herein, provides more efficient construction of power regulators and PDN in general, since each battery is intended for specific modules and has characteristics that are for the optimum performance of that module. In various embodiments, as depicted in FIG. 12(b), each power regulator's structure and topology is more efficient and simpler than the regulator that would be required when using a single battery on chip, because each regulator needs only supply voltage and current for a single module.

In various embodiments the distributed battery arrangement divides large drawn current into smaller currents to address the issue with large loads. Each module in this case may have its own battery and LDO. As a result, each LDO's output transistor will eventually be much smaller according to Eqn. (2) which implies a simpler hence more efficient pre-driver. In various embodiments, the difference of VIN−VDD can be reduced when using distributed batteries because each battery may be designed based on the required voltage level of each module. Therefore, in various embodiments, by using distributed batteries, the overall 3D IC power loss will be reduced.

Therefore, since each module in a heterogeneous 3D IC may require its own supply voltage for optimal performance, each of the distributed batteries may provide such supply voltage to a corresponding functional module. In various embodiments, the power delivery circuit corresponding to each battery and/or each functional module may be configured to provide such voltage levels that may also be adjusted over time, e.g., due to the use of dynamic voltage scaling (DVS) to minimize the energy usage of various functional modules such as digital processors.

A DC-DC converter may be used to deliver the voltage supply to the corresponding module. However, using DC-DC converters, when combined with a single battery for a 3D IC, may lead to an increase in die area, the number of passive components, and system volume. However, DC-DC converters, both linear and switching types, may be used for converting and regulating DC voltages with a higher efficiency when used with distributed batteries.

For some applications, larger switching mode power delivery circuits, as for example shown in FIG. 11(b), is favored over smaller linear power delivery circuit, as for example shown in FIG. 11(a), due to their high power efficiency, which ideally may reach 100%.

In various embodiments, the distributed battery system uses two or more power deliver interfaces, where a power delivery interface of the two or more power delivery interfaces may correspond to the battery. In various embodiments, a power delivery interface includes a linear power delivery circuit 1100, as for example shown by FIG. 11(a). The power delivery circuit may include an amplifier configured to receive an output of the battery and provide an amplified output to at least the corresponding electronic module. In various embodiments, the amplifier is a linear amplifier and includes a power transistor 1102. The power transistor 1102 may be configured to receive the output of the battery at the source of the power transistor, and generate the amplified output at the drain of the power transistor.

In various embodiments, the linear amplifier includes an operational amplifier 1104. The operational amplifier 1104 may be configured to receive a negative feedback voltage, and compare the negative feedback voltage with a reference voltage, wherein the reference voltage is a bandgap voltage configured to remain independent of power variations of the battery, temperature changes, and load variations of the corresponding electronic module. The operational amplifier 1104 may be configured to generate an error output 1106, and provide the error output to a gate of the power transistor 1102.

In various embodiments, the linear amplifier includes a linear voltage divider 1108. The linear voltage divider may be configured to receive the amplified output from the drain of the power transistor and generate the negative feedback voltage by linearly dividing the amplified output from the drain of the power transistor using a linearly variable resistor.

In various embodiments, compact switching power converters may be designed to operate at higher switching frequencies, but this may lead to increased parasitic impedance, which reduces the overall power efficiency of the power delivery system. Therefore, using switching DC-DC regulators may be challenging for on-chip power conversion due to their large physical size and technology constraints, making on-chip integration difficult. Therefore, in various embodiments, when delivering high-quality power to the load circuitry within limited space, on-chip linear regulators may be used. In examples where a small input-output voltage differences are required, linear regulators may be preferred over switching power supplies. In some examples of distributed batteries, and when providing power to certain functional modules, linear regulators may be used.

As described with respect to Eqn. 2, the size, complexity, and efficiency of a linear regulator may generally linked to two parameters: the maximum load current and the dropout voltage. And an increase in the peak load current IDD results in a larger power transistor, leading to a more complex gate driver circuit.

In various embodiments where distributed batteries are used, since each linear regulator is responsible for providing current for only one module, the maximum current is lower compared to the conventional case where the linear regulator should provide current for several modules with the same voltage level. In this situation, multiple smaller linear regulators are needed to supply the necessary voltage and current for the entire system. On the other hand, the size and complexity of the error amplifier in the linear regulator are directly influenced by the load regulation requirements. If tight load regulation is needed, the amplifier may need to be designed with higher gain and better precision. This can result in a larger and more complex circuit implementation, potentially involving more components and increased design complexity. Similarly, in the distributed battery structure, tight load regulation is less required compared to the conventional case with a single battery.

In various embodiments, using distributed batteries is also beneficial for reducing power loss and improving the efficiency of linear regulators within 3D ICs. The power loss within an LDO can be described as follows:

$${P}_{Linear} \approx ( {V}_{IN} - {V}_{DD} ) . {I}_{D}$$

Where, VDD is the regulated and desired operating voltage level delivered to the module, VIN is the voltage provided by battery and ID is the total current drawn by different modules from LDO. As a result, the power loss in a linear converter rises with a greater VIN−VDD drop, decreasing the converter's power efficiency. This issue is made worse when the needed voltage level from the LDO is substantially lower than the battery voltage level.

The power loss within an LDO may be more accurately described as:

$${P}_{Linear} \approx ( {V}_{IN} - {V}_{DD} ) . {I}_{DD} + {I}_{Q} {V}_{IN}$$

Where IQ is the quiescent current of the voltage regulator. As the input-output voltage difference increases in a linear DC-DC converter, the power dissipation within the linear voltage regulator also increases. By employing distributed batteries, each battery can be designed to generate a slightly higher voltage than the desired operating voltage (VDD) of the load circuitry (a corresponding functioning module). This approach helps reduce the input-output voltage difference in the linear DC-DC converter, thereby minimizing power dissipation and improving overall energy efficiency. Assuming IQ<<IDD, the efficiency of the LDO is approximately η=VDD/VIN, which is equal to the voltage transformation ratio. In various embodiments, the distributed batteries concept, by reducing the input-output voltage difference, contributes to enhancing the efficiency of linear regulators.

In various embodiments, the implementation of distributed batteries may further enable individual optimization of linear regulators to maximize their efficiency and simplify the design of each regulator. As a result, the overall volume, power consumption, and operating lifetime of the 3D IC can be enhanced.

### Cost, Size and Form Factor

Manufacturing a large battery inside 3D ICs that can provide appropriate voltage and current may be costly. Smaller batters are therefore more desirable and may be more cost effective for fabrication. In various embodiments herein, using distributed batteries the efficiency of on-chip batteries may be increased by arranging the batteries to provide additional space inside a limited volume.

In various embodiments herein, the batteries may be positioned on the perimeter of the IC, for example such that the batteries form surrounding walls. Referring now to FIGS. 13(a) and 13(b) schematic diagrams illustrating a distributed battery system where the batteries are position arounds the walls of IC (which may be referred to as “Batteries Positioned Around the Walls” technique) are provided in accordance with various embodiments of the present disclosure. FIG. 13(a) illustrates a side view and FIG. 13(b) illustrates a top view of the distributed battery system in accordance with various embodiments. For example, battery D (e.g., referred to as a third battery) may be disposed on a first side wall of the three-dimensional integrated circuit, configured to provide power to at least one of the functional modules. For example, battery E (e.g., referred to as a fourth battery) may be disposed on a second side wall of the three-dimensional integrated circuit, configured to provide power to at least one of the functional modules. For example, battery F (e.g., referred to as a fifth battery) may be disposed on a third side wall of the three-dimensional integrated circuit, configured to provide power to at least one of the functional modules. For example, battery G (e.g., referred to as a sixth battery) may be disposed on a fourth side wall of the three-dimensional integrated circuit, configured to provide power to at least one of the functional modules.

In various embodiments, placing the batteries on the perimeter may provide a significant amount of space for the incorporation of SSBs in heterogeneous 3D ICs. In various embodiments, the batteries in the distributed battery system may be placed on the perimeter (or around the walls) in addition to the battery layers in a vertical stack as previously described. Placing some of or all the batteries on the perimeter of the IC may be desirable when the IC includes a high number of various module layers.

### Additional Energy Storage and Cooling

Since 3D ICs often require a high power density per area, their overall form factor can be minimized by positioning additional batteries around the walls of the module as described above and illustrated by FIGS. 13(a) and 13(b). In accordance with various embodiments, this arrangements also reduces thermal resistance by increasing the battery surface area in contact with the ambient.

Providing proper cooling is a significant step when designing and/or implementing 3D heterogeneous ICs. 3D heterogeneous ICs, several modules may be piled on top of each other, each producing heat. This heat should be transferred out of the 3D IC structure as much as possible, so that the system's performance does not degrade. In various embodiments, any of and/or a combination of a passive heat sink and the “Batteries Positioned Around the Walls” technique may provide proper cooling for 3D ICs.

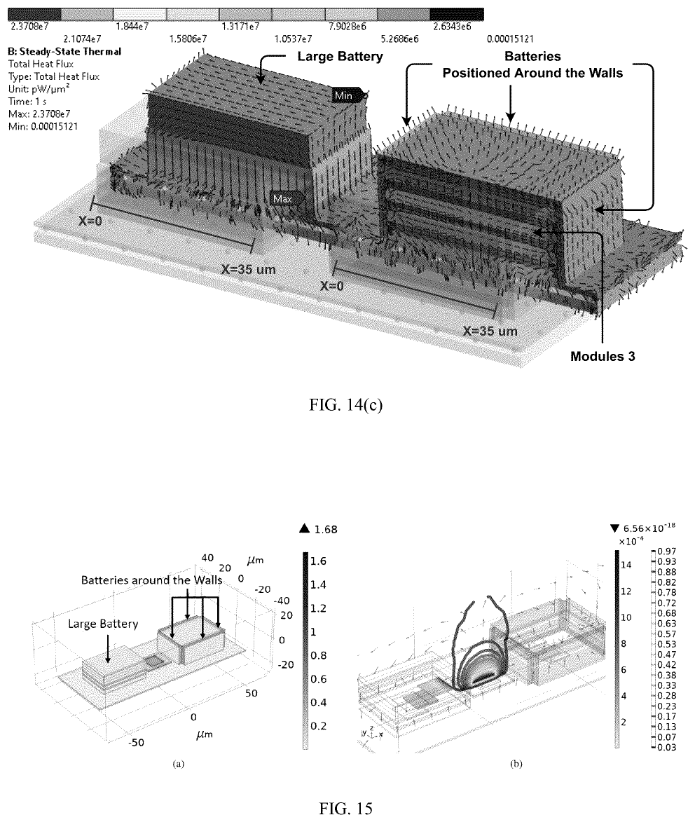

FIG. 14(a) and FIG. 14(b) provide schematic diagrams illustrating batteries positioned around the walls of an IC functioning as heat sink, thereby helping to transfer heat from the 3D IC to the outside environment, in accordance with various embodiments of the present disclosure. As shown in FIG. 14(a) and FIG. 14(b), horizontally-oriented batteries can absorb heat from the modules and efficiently transport it to the wall-mounted batteries, thereby cooling the entire structure. FIG. 14(a) illustrates a side/top view and FIG. 14(b) illustrates a front view in accordance with various embodiments. In accordance with various embodiments, the “Batteries Positioned Around the Walls” technique may provide a large surface area to assist spreading out internally generated heat to the outside of 3D ICs. In various embodiments, distributed batteries, in conjunction with vertical batteries attached to the walls, may provide a highly efficient cooling system for 3D ICs. In various embodiments, horizontally distributed batteries may absorb heat created by modules and components and transport it to the batteries around the wall, where the batteries around the wall in turn dissipate the heat to the environment, thereby cooling the entire IC. The FIGS. 14(a) and 14(b) illustrate how the batteries around the walls can help to transfer heat from the 3D ICs to the outside.

FIG. 14(c) shows the simulated heat flux inside a 3D IC structure for both the single battery (left) and distributed batteries (combination of horizontal and vertical batteries, right) structures. For simplicity, all modules within both structures were assumed to generate the same amount of heat. For the single battery structure, all heat flux from the upper modules finds its way to the lower modules, leading to high thermal resistance. By contrast, the proposed structure (combination of horizontal and vertical batteries) can easily conduct heat to the sides of the 3D IC structure with the help of an appropriate inter-layer material, thus decreasing the thermal resistance.

FIG. 14(d) plots heat flux data from FIG. 14(c) along a path across the surface of a single module. While the single battery structure experiences the same amount of heat flux throughout the module, the proposed structure redirects most of the heat flux to the edges, resulting in improved thermal management, reliability, performance, and power consumption.

### Antenna Radiation/EM Shielding

In various embodiments, designing the 3D IC may require confining mounting antenna(s) and/or other radiation mechanisms on top or bottom modules. This may be because other modules should not function as an obstacle or barrier to the transmitting signals or received signals from a far end. The available area on top and bottom modules, on the other hand, may be limited due to the existence of analog components such as Power amplifiers, oscillators, filters, and other bulky structures. Furthermore, multi antenna arrays as receiver or transmitter arrays may be required in many cases and applications. Using multi antenna arrays as receiver or transmitter arrays, also known as MIMO communication systems, may provide numerous benefits and advantages in terms of spectral efficiency.

In various embodiments of the present disclosure, using the batteries positioned around the walls may provide larger surface areas for constructing and/or mounting various types of antennas or other transmitting/receiving devices. Therefore, various embodiments of the present disclosure provide for building MIMO and other sophisticated communication systems.

In various embodiments, the batteries positioned around the walls arrangement may also provide electromagnetic shielding. Several components and modules in heterogeneous 3D ICs may be constantly functioning and/or switching on or off. These voltage transitions between high and low along the traces may generate a significant amount of undesired EM radiations that can be transmitted to the outside of the IC. These electromagnetic emissions have the potential to degrade the performance of neighboring systems. In various embodiments, vertical batteries on the permitter walls may provide a good degree of insulation and act as a barrier for such EM radiations. In various embodiments, the housing of the batteries placed on the permitter walls may include conductive materials, hence providing two layers of shielding against EM radiations.

For example, with reference to FIGS. 13(a) and 13(b), at least one of the batteries may include a battery housing that is heat conductive (for heat management purposes as previously described) and/or reduces electromagnetic interference (for EMI shielding). For example, the first battery may have a first battery housing, the second battery may have a second battery housing, the third battery (e.g. battery D) may have a third battery housing, the fourth battery (e.g. battery E) may have a fourth battery housing, the fifth battery (e.g. battery F) may have a fifth battery housing, and the sixth battery (e.g. battery G) may have a sixth battery housing.

In various embodiments, for heat management purposes as previously described, the first, second, third, fourth, fifth, and sixth battery housings may include a heat conductive material, and the third, fourth, fifth, and sixth battery housings are configured to physically couple to the first and second battery housings, and transmit heat generated by the first and second electronic module from the first and second battery housings to an outside environment as for example shown in FIGS. 13(a), 13(b) and 14(a) and 14(b).

In various embodiments, the third, fourth, fifth, and sixth battery housings may include an electromagnetic field attenuating material (such as metal or any conductive material) and are configured to reduce an external electromagnetic interference on the first and second electronic modules.

The ability of vertically mounted batteries to act as a two-layer electromagnetic shield offers benefits by effectively reducing radiated EMI. The E″-Field shielding provided by a typical battery geometry is evaluated through multiphysics simulations in accordance with various embodiments of the present disclosure. For this purpose, a 3D model of the conventional and proposed systems on a substrate are built, as shown in FIG. 15(a). The system on the left has one large battery deposited at the top, while that on the right has four batteries distributed on different layers and four additional batteries mounted on the walls. The current collector materials of the batteries were assumed to be aluminum (cathode) and copper (anode).

FIG. 15(a) depicts the E″-field generated by a 1 V source is applied at a distance of 30 μm from both systems. The low field amplitudes on the surfaces of the 3D ICs qualitatively shows that they both act as good EM shields. FIG. 15(b) shows a more quantitative comparison of the shielding provided by the two systems. I accordance with the rest results, the system with distributed horizontal and vertical batteries provides ˜1000× (i.e., 60 dB) better shielding than the conventional structure.

As described above, another advantage of the distributed batteries concept within 3D ICs is its ability to mitigate the potential impact of internal electromagnetic fields generated by batteries and charging processes, thereby enhancing the system's reliable operation. The proposed approach effectively addresses this issue by strategically distributing the batteries throughout the system, resulting in lower currents required from each battery compared to a single large battery. Consequently, the electromagnetic emissions produced by individual batteries are significantly reduced and spread across the system. This distribution of electromagnetic emissions prevents the high concentration of electromagnetic interference in specific areas, creating a more favorable environment for noise-sensitive or electromagnetic-sensitive modules to operate reliably. Furthermore, the reduced electromagnetic emissions from each distributed battery synergize with conventional shielding techniques. With lower levels of electromagnetic radiation, shielding can more efficiently minimize the impact on the surrounding EM, ensuring sustained system performance. Moreover, the proposed approach's distributed nature allows for greater flexibility in routing the charging paths for each battery. By strategically distributing these paths in locations less susceptible to electromagnetic interference, the impact of internal electromagnetic fields on sensitive circuitry is minimized. These considerations collectively contribute to improved electromagnetic compatibility and a reduction in the concentration of electromagnetic radiation within the system. As a result, the distributed batteries concept provides enhanced electromagnetic interference management, bolstering the overall reliability and efficiency of 3D IC systems.

### Applicability

As described above, SiP and advanced packaging technologies such as 2.5D and 3D packaging may provide for the integration of multiple chips and components in semiconductor manufacturing and development. Using a combination of 2.5D and 3D IC packages may be beneficial in a wide range of applications due to the many advantages they offer, such as improved performance, smaller form factor, and reduced power consumption. This is particularly useful in applications such as CPUs, mobile application processors, and display driver ICs, where high-performance computing is required in a compact form factor.

In various embodiments, the utilization of the distributed battery technique within SiP or advanced packaging technologies like 2.5D and 3D brings notable benefits. Firstly, by incorporating distributed batteries, power delivery becomes more localized and efficient, reducing the need for long power traces and minimizing power losses. This, in turn, enables the design of compact and densely integrated SiP solutions with improved power integrity. Secondly, the use of distributed batteries allows for flexible power management, as each module or sensor can be powered independently. This flexibility facilitates dynamic power allocation and optimization, enhancing the overall system performance and energy efficiency. Additionally, distributed batteries can be strategically placed near power-hungry components, mitigating voltage drop issues and reducing the impact of power supply noise.

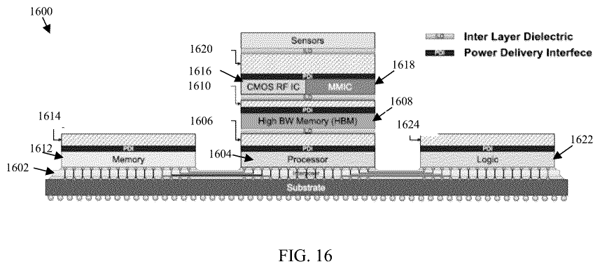

In various embodiments, the distributed battery approach can enhance the reliability and fault tolerance of SiP systems. In case of battery failure, only the affected module is affected, while the rest of the system remains operational. This fault isolation capability reduces the impact of failures and simplifies maintenance and repair processes. As shown in FIG. 16, the distributed battery technique in accordance with various embodiments of the present disclosure, is applicable to SiP, 2.5D, 3D IC packages and their combination. Furthermore, the benefits of the presented distributed battery approach extend beyond SiP, 2.5D, and 3D IC packages. It is also applicable to monolithic ICs, where all components are integrated on a single chip. Even in this scenario, the distributed battery technique proves to be advantageous.

In various embodiments, with reference to FIG. 16, an electronic device 1600 is provided. The electronic device 1600 may include a substrate configured to support the electronic device, an interposer 1602 electronically coupled to the substrate, a first electronic module 1604 electronically coupled to the interposer.

The electronic device may include a first battery 1606 electronically coupled to the first electronic module 1606 and configured to provide power to the first electronic module. The electronic device may include a second electronic module 1608 configured to electronically couple to the first electronic module.

In various embodiments, the electronic device includes a second battery 1610 electronically coupled to the second electronic module and configured to provide power to the second electronic module. In various embodiments, the electronic device includes a third electronic module 1612 electronically coupled to the interposer 1602 and a third battery 1614 electronically coupled to the third electronic module and configured to provide power to the third electronic module.

Various electronic modules may include any of a processor, a memory, an RF module, a sensor, a monolithic microwave integrated circuit (MMIC), etc. Examples shown in FIG. 16 for each electronic module is for illustration and exemplary purposes and each electronic module may be or include any other modules different from what is shown in FIG. 16.

In various embodiments, the first electronic module, the first battery, the second electronic module and the second battery are vertically stacked with respect to the substrate. In various embodiments, the first battery is placed between the first and second electronic modules.

In various embodiments, the electronic device further includes a plurality of through-silicon via (TSV) connections, for example as illustrated by FIG. 4. The TSV connections may be configured to electronically couple the first electronic module with the second electronic module, and transfer data between the first electronic module and the second electronic module. In various embodiments, the plurality of TSV connections surround the first battery.

In various embodiments, the electronic device includes a plurality of through-silicon via (TSV) connections, for example as illustrated by FIG. 5. The TSV connections may be configured to electronically couple the first electronic module with the second electronic module, and transfer data between the first electronic module and the second electronic module. In various embodiments, the first battery comprises a plurality of through holes and the plurality of TSV connections pass through the through holes of the first battery.

In various embodiments, the first battery is configured to provide power to the first electronic module and the second electronic module in case of a failure of the second battery. In various embodiments, the first electronic module and the second electronic module are electronically coupled through one or more electronically connections inside the interposer, as for example shown by FIG. 16.

In various embodiments, the electronic device further includes a first power delivery interface (PDI) electronically coupled between the first battery and the first electronic module, wherein the power deliver interface includes a voltage regulator configured to regulate the output voltage of the first battery for the first electronic module.

In various embodiments, the electronic device further includes a fourth electronic module 1616 electronically coupled to the second battery 1610, and a fifth electronic module 1618 is electronically coupled to the second battery and placed in a same layer with the fourth electronic module. In various embodiments, the fourth and fifth electronic modules are stacked vertically with respect to the second battery, and the second battery is configured to provide power to at least one of the second, fourth, or fifth electronic modules.

In various embodiments, the electronic device includes a fourth battery 1620 placed on the fourth and fifth electronic modules, and the fourth battery may be configured to provide power to the fourth and fifth electronic modules.

In various embodiments, the electronic device 1600 includes various interlayer dielectric (ILD) layers. An ILD may be placed between a battery and an adjacent electronic module to which the battery does not provide power.

In various embodiments, the electronic device 1600 may include various other stacks of batter(ies) and electronic module(s), for example electronic module 1622 and battery 1624.

### Operating Temperature Range

In various embodiments, given the high energy density of 3D ICs, some applications require solid state batteries (SSBs) that can operate up to ˜70° C. For example, using a complex hydride as a solid electrolyte may allow internal resistance to be reduced, thus enabling Li-ion SSBs that operate at temperatures up to 150° C. with <10% degradation in capacity. This feature makes these batteries a perfect fit for incorporation within 3D integrated circuits. In various embodiments, some and/or all of the batteries may be solid state batteries.

### Self-Protection And Smart Thermal Control

In various embodiments, safe usage of distributed batteries may require protecting against short-circuit faults, which can damage the 3D IC and its surroundings through excessive heat generation (i.e., thermal runaway). Physical safety measures such as fuses are valuable but may only offer one-time protection with no guarantee of system recovery after the fault is cleared. The situation can be improved via active thermal control. For example, the distributed batteries can use “smart” thermos-responsive polymer electrolytes that prevent thermal runaway by automatically transitioning between low and high conductivity states.

### Systematic Approach to Determining Distributed Battery Requirements

The determination of appropriate output voltage levels, capacities and the minimum number of distributed batteries in the 3D IC designs in accordance with various embodiments of the present disclosure, may take into account a comprehensive set of factors, including the power requirements and profiles of the modules, system constraints, and performance goals. This process may follow a systematic approach, commencing with a detailed analysis of the power profiles of each module. Peak and average power consumption, as well as specific power requirements during different operational states, are considered to identify optimal voltage levels and capacity ranges that precisely align with the power needs of the electronic modules. Consequently, the required number of batteries to fulfill these requirements is determined. Additionally, the battery-to-module relationship is established based on compatibility factors such as chemistry, voltage, and current requirements.

In various embodiments, for effective power distribution, a strategy is developed, taking into account physical placement, interconnectivity, and thermal aspects to ensure seamless power delivery to each module from the distributed batteries. The battery distribution and configuration may be refined using simulation tools and optimization techniques, with the number of batteries being iteratively adjusted to achieve the most efficient distribution while satisfying all module power requirements. The process may also include a thorough consideration of factors like redundancy, system reliability, cost, and design constraints. Furthermore, the maximum number of batteries inserted inside 3D IC structure is carefully limited, taking cost and yield considerations into account. The selection of the appropriate electrochemistry entails a thorough evaluation of various battery types, encompassing factors such as energy density, power density, cycle life, safety features, and cost-effectiveness. In various embodiments, the objective is to opt for battery chemistries that strike the most advantageous balance between performance, reliability, and cost-effectiveness for the intended application.

One of the main issues with high-power modules such as processors, DRAM, or power converters is overheating, which can degrade the performance of nearby batteries. This is because these modules generate a significant amount of heat, which can be transferred to the batteries through conduction or radiation, leading to an increase in their operating temperature. This can pose a risk of elevated temperatures near the batteries, potentially compromising their performance and reliability. The degradation of battery performance can manifest as reduced capacity, increased internal resistance, and diminished overall power delivery. Batteries also reduce the interconnect density between adjacent modules, which may not be acceptable when very high inter-module bandwidths are required. In such cases, a semi-distributed structure in which two adjacent modules can share one battery may be used, in accordance with various embodiments of the present disclosure. Alternatively, vertical batteries mounted to the walls can be used to power some of the modules, as previously described. This approach may include using thin, high-capacity batteries that can be mounted vertically on the walls of the system. These batteries provide a high-power density and do not take up much space, making them an attractive option for powering modules that require a lot of power.

Various embodiments of the present disclosure provide integrating distributed micro-batteries within heterogeneous 3D ICs for improved energy efficiency and performance. Various embodiments of distributed batteries address the challenges associated with conventional power distribution approaches and offers several benefits. For example, the utilization of one battery per module reduces heat generation and improves thermal performance. The simulation results demonstrate a more uniform temperature distribution of at least 40 percent compared to the conventional approach. In various examples, the integration of distributed batteries also enhances power delivery by reducing voltage drops and electromagnetic interference. The smaller power supply loops and increased isolation between modules may result in decreased radiated EMI and limit noise propagation. Furthermore, the use of distributed batteries improves reliability by providing redundancy and prolonging battery lifetime through controlled discharge rates and reduced internal heat generation. Additionally, the positioning of additional batteries around module walls improves thermal management, reliability, performance, and power consumption by reducing thermal resistance and redirecting heat flux. The vertically-mounted distributed batteries act as effective electromagnetic shields, providing significant shielding improvement compared to conventional structures. For example, the proposed technique offers approximately 1000 times (60 dB) better shielding.

### CONCLUSION

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A three-dimensional integrated circuit comprising:
a first electronic module disposed on a substrate of the three-dimensional integrated circuit;
a first battery disposed on the first electronic module and electronically coupled to the first electronic module, wherein the first battery is configured to provide power to the first electronic module;
a second electronic module disposed on the first battery; and
a second battery disposed on the second electronic module and electronically coupled to the second electronic module, wherein the second battery is configured to provide power to the second electronic module.

2. The three-dimensional integrated circuit of claim 1, wherein the first electronic module comprises at least one of a first processor, a first memory, a first radio frequency circuit, or first a sensor circuit and the second electronic module comprises at least one of a second processor, a second memory, a second radio frequency circuit, or a second sensor circuit.

3. The three-dimensional integrated circuit of claim 1 further comprising a plurality of through-silicon via (TSV) connections configured to:
electronically couple the first electronic module with the second electronic module; and
transfer data between the first electronic module and the second electronic module, wherein the plurality of TSV connections surround the first battery.

4. The three-dimensional integrated circuit of claim 1 further comprising a plurality of through-silicon via (TSV) connections configured to:
electronically couple the first electronic module with the second electronic module; and
transfer data between the first electronic module and the second electronic module, wherein the first battery comprises a plurality of through holes and the plurality of TSV connections pass through the through holes of the first battery.

5. The three-dimensional integrated circuit of claim 1, further comprising:
a third battery disposed on a first side wall of the three-dimensional integrated circuit, and configured to provide power to at least one of the first or second electronic modules;
a fourth battery disposed on a second side wall of the three-dimensional integrated circuit, and configured to provide power to at least one of the first or second electronic modules;
a fifth battery disposed on a third side wall of the three-dimensional integrated circuit, and configured to provide power to at least one of the first or second electronic modules; and
a sixth battery disposed on a fourth side wall of the three-dimensional integrated circuit, and configured to provide power to at least one of the first or second electronic modules.

6. The three-dimensional integrated circuit of claim 5, wherein the first battery comprises a first battery housing, the second battery comprises a second battery housing, the third battery comprises a third battery housing, the fourth battery comprises a fourth battery housing, the fifth battery comprises a fifth battery housing, and the sixth battery comprises a sixth battery housing.

7. The three-dimensional integrated circuit of claim 6, wherein the first, second, third, fourth, fifth, and sixth battery housings comprise a heat conductive material, and the third, fourth, fifth, and sixth battery housings are configured to:
physically couple to the first and second battery housings; and
transmit heat generated by the first and second electronic module from the first and second battery housings to an outside environment.

8. The three-dimensional integrated circuit of claim 6, wherein the third, fourth, fifth, and sixth battery housings comprise an electromagnetic field attenuating material and are configured to reduce an external electromagnetic interference on the first and second electronic modules.

9. A three-dimensional integrated circuit comprising:
two or more electronic modules;
two or more batteries, wherein a battery of the two or more batteries is configured to provide power to at least a corresponding electronic module of the two or more electronic modules; and
two or more power deliver interfaces, wherein a power delivery interface of the two or more power delivery interfaces corresponds to the battery, and the power delivery interface comprises an amplifier configured to receive an output of the battery and provide an amplified output to at least the corresponding electronic module.

10. The three-dimensional integrated circuit of claim 9, wherein the amplifier is a linear amplifier and comprises a power transistor configured to:
receive the output of the battery at the source of the power transistor; and
generate the amplified output at a drain of the power transistor.

11. The three-dimensional integrated circuit of claim 10, wherein the linear amplifier comprises:
an operational amplifier configured to:
receive a negative feedback voltage;
compare the negative feedback voltage with a reference voltage, wherein the reference voltage is a bandgap voltage configured to remain independent of power variations of the battery, temperature changes, and load variations of the corresponding electronic module;
generate an error output; and
provide the error output to a gate of the power transistor; and
a linear voltage divider, the linear voltage divider configured to:
receive the amplified output from the drain of the power transistor; and
generate the negative feedback voltage by linearly dividing the amplified output from the drain of the power transistor using a linearly variable resistor.

12. An electronic device comprising:
a substrate configured to support the electronic device;
an interposer electronically coupled to the substrate;
a first electronic module electronically coupled to the interposer;
a first battery electronically coupled to the first electronic module and configured to provide power to the first electronic module;
a second electronic module configured to electronically couple to the first electronic module;
a second battery electronically coupled to the second electronic module and configured to provide power to the second electronic module;
a third electronic module electronically coupled to the interposer; and
a third battery electronically coupled to the third electronic module and configured to provide power to the third electronic module.

13. The electronic device of claim 12, wherein the first electronic module, the first battery, the second electronic module and the second battery are vertically stacked with respect to the substrate.

14. The electronic device of claim 13, wherein the first battery is placed between the first and second electronic modules.

15. The electronic device of claim 14, further comprising a plurality of through-silicon via (TSV) connections configured to:
electronically couple the first electronic module with the second electronic module; and
transfer data between the first electronic module and the second electronic module, wherein the plurality of TSV connections surround the first battery.

16. The electronic device of claim 14, further comprising a plurality of through-silicon via (TSV) connections configured to:
electronically couple the first electronic module with the second electronic module; and
transfer data between the first electronic module and the second electronic module, wherein the first battery comprises a plurality of through holes and the plurality of TSV connections pass through the through holes of the first battery.

17. The electronic device of claim 12, wherein the first battery is configured to provide power to the first electronic module and the second electronic module in case of a failure of the second battery.

18. The electronic device of claim 12, wherein the first electronic module and the second electronic module are electronically coupled through one or more electronically connections inside the interposer.

19. The electronic device of claim 12 further comprising a first power delivery interface electronically coupled between the first battery and the first electronic module, wherein the power deliver interface includes a voltage regulator configured to regulate an output voltage of the first battery for the first electronic module.

20. The electronic device of claim 12 further comprising:
a fourth electronic module electronically coupled to the second battery; and
a fifth electronic module electronically coupled to the second battery and placed in a same layer with the fourth electronic module, wherein the fourth and fifth electronic modules are stacked vertically with respect to the second battery, and wherein the second battery is configured to provide power to at least one of the second, fourth, or fifth electronic modules.
